(19) United States
(12) Patent Application Publication
(10) Pub. No.: US 2026/0282271 A1
(43) Pub. Date: Sep. 17, 2026

(54) HIGH EFFICIENCY COOLING FOR COMPUTE SYSTEMS

(71) Applicant: NVIDIA CORPORATION, Santa Clara, CA (US)

(72) Inventors: Elad Mentovich, Tel Aviv (IL); Ryan Albright, Beaverton, OR (US); John Norton, Houston, TX (US); Ken Misin, Santa Rosa, CA (US); Sam Hand, Sugar Land, TX (US)

(21) Appl. No.: 19/080,349

(22) Filed: Mar. 14, 2025

(51) Int. Cl. H05K 7/20; G06F 1/20

(52) U.S. Cl. CPC H05K 7/20154; G06F 1/20; H05K 7/20172; H05K 7/20209; H05K 7/20727; G06F 2200/201

(57) ABSTRACT

A high-efficiency cooling system for a compute system comprises a compute tray cooling system and a switch tray cooling system. The compute tray cooling system comprises a plurality of fans and a T-shaped heat sink bank secured to a substrate of the compute tray. The switch tray cooling system comprises an external fan bank to direct air flow through a plurality of switch trays. The compute tray cooling system and the switch tray cooling system operate in tandem to provide optimal cooling for the compute system, which may selectively active the switch tray cooling system depending on whether compute resources within the switch tray are active.

### BACKGROUND

As artificial intelligence and/or machine learning use increases, the amount of information being communicated between large clusters of computing resources (e.g., graphical processing units (GPUs), central processing units (CPUs), data processing units (DPUs), and/or the like) is also increasing. As these computing resources process data (e.g., during machine learning and/or inference processes), these compute resources generate large amounts of heat that must be dissipated to maintain desired processing performance of the computing resources. Computing resources are cooled by air cooling and/or liquid cooling to direct heat away from the computing resources. However, as the processing capabilities of computing resources increases, the amount of heat generated by those computing resources continues to increase, and therefore there is a continuous need for new, more efficient cooling mechanisms.

### GENERAL DESCRIPTION

The amount of heat generated by computing resources in data centers has remained a difficult design challenge for new compute tray and/or switch tray designs for inclusion in data centers. While the amount of heat generated by computing resources in each of compute trays and switch trays as gradually increased over time with increased computing capabilities, the amount of space available for heat dissipation mechanisms has remained generally stable over time. In short, the processing power (and heat generation) in data centers has become more dense in a relatively small tray, and new heat management systems are required to keep pace with the increase in heat density within data centers. While this creates space efficiencies within a rack, it limits the amount of space available for heat sinks within the tray and on the substrate (e.g., printed circuit board (PCB)) in the tray. AI factories have constant challenge of choosing which cooling solutions are preferred, typically selecting between air cooling or liquid cooling (and potentially adding immersive and/or cryo-based cooling in the future), which creates the challenges of several design per customer. The embodiments discussed herein solve this problem utilizing an air cooling system with cascaded, serviceable heat sinks having a unique configuration within compute trays that allow for efficient air cooling of compute trays, that work in tandem with modular external fan banks utilized to cool switch trays as those switch trays are used. The modular external fan banks may be expanded depending on the size of the switch trays (e.g., as more switch trays are added, the size of the external fan bank may be expanded). To increase heat transfer capabilities within these space-limited trays, the fin assembly and vapor chambers of the heat sinks are expanded in the width direction on the board (adding “outriggers” to the heat sinks) to increase the heat sink fin area. This heat sink configuration enables air cooling of a module with high power chips very close together. This limits available surface area for heat sink fins to be built on top of a substrate. In addition, this module is thick and on top of a host board, limiting available fin height. But extending the vapor chamber and fin assemblies in the width direction (outriggers) the fin area can be increased and more effective air cooling is possible. In addition, fins extend down on the sides from the module top surface and rubber mechanical stop provide support while enabling a die reference thermal design for the heat sink.

The air cooling system discussed herein incorporates multiple cooling mechanisms with strategic placement relative to compute trays and switch trays in a server rack that work in tandem to efficiently pull cooling air through the compute trays and switch trays to efficiently cool the computing resources in each tray type. Specifically, the air cooling system includes compute tray cooling systems and a switch tray cooling system. The compute tray cooling systems are positioned within each compute tray. Each compute trays include T-shaped heat sink banks that extend between multiple computing resources in a tray and behind those computing resources (e.g., between a rear wall of a tray housing and the computing resources) and a plurality of internal fans in a fan bank located on an opposite side of the computing resources. The plurality of internal fans in the compute trays are arranged in a 1-dimensional array (e.g., a row). The compute tray cooling system, comprising the internal fans and heat sink bank, cool the computing resources by blowing air across the computing resources and the heat sink bank.

The compute tray cooling system works in tandem with a switch tray cooling system comprising one or more external fan banks configured to cool a plurality of switch trays arranged in a switch tray stack. The switch tray stack may be arranged at a bottom of a compute tray stack within a housing or rack. The switch tray cooling system comprises a external fan bank comprising a modular 2-dimensional array of external fans (e.g., a 3-fan by 3-fan array) positioned at a rear of the switch trays. In some embodiments, the switch tray cooling system comprises multiple external fan arrays (e.g., an external fan array arranged on either side of a bus bar connector located centrally to the switch trays). The switch tray cooling system additionally comprises a plenum attached to each fan bank and which extends to openings in a backside of the switch trays in the switch tray stack. The fan bank is a high-pressure fan bank that directs air into the switch trays, and which creates a low pressure region proximate the rear of the compute trays and switch trays to further increase the efficiency of the compute tray cooling system.

Various embodiments are directed to a cooling system comprising: at least one compute tray comprising one or more computing resources on a substrate and a compute tray cooling system comprising one or more internal fans and at least one heat sink attached to the substrate; a plurality of switch trays; and at least one fan bank comprising one or more fans at a backside of a plurality of switch trays; wherein the compute tray cooling system and the at least one fan bank collectively provide cooling based at least in part on a workload performed by the at least one compute tray and the plurality of switch trays.

In certain embodiments, the at least one fan bank comprises a plurality of fans that collectively move air through the backside of the plurality of switch trays. In various embodiments, the at least one fan bank comprises a quantity of fans and wherein the plurality of switch trays is defined as a quantity of switch trays less than the quantity of fans. In certain embodiments, the at least one fan bank comprises a plenum extending to the backside of the plurality of switch trays. In various embodiments, the plurality of switch trays are vented to accommodate air flow through the plenum. In certain embodiments, the one or more fans of the at least one fan bank operate to provide cooling for the plurality of switch trays when the plurality of switch trays perform a portion of the workload. In various embodiments, the at least one compute tray comprises a plurality of compute resources and the heat sink comprises T-shaped heat sink fin banks extending between the plurality of compute resources on the substrate. In certain embodiments, the compute tray further comprises a plurality of fans. In certain embodiments, the compute resources are located between the plurality of fans and the heat sink fin banks, so that the plurality of fans blow air across the compute resources to the heat sink fin banks. In various embodiments, the plurality of fans of the compute tray are operable in tandem with the at least one fan bank based at least in part on whether the plurality of switch trays are operating to connect a plurality of computing resources within a plurality of compute trays.

Certain embodiments are directed to a compute tray comprising: a substrate; a plurality of computing resources on the substrate; and a heat sink assembly on the substrate, wherein the heat sink assembly comprises fin banks arranged in a T-shape.

In certain embodiments, the compute tray further comprises a plurality of fans mounted on the substrate. In certain embodiments, the plurality of fans are mounted in a row. In various embodiments, the plurality of computing resources are located between the heat sink assembly and the plurality of fans. In certain embodiments, the compute tray further comprises a housing to enclose the substrate, the plurality of computing resources, and the heat sink assembly, wherein the substrate defines a vented rear face to allow air to pass from an interior of the housing to an exterior of the housing.

Various embodiments are directed to a method of cooling a compute system, the method comprising: directing air across a T-shaped heat sink bank within a compute tray of a plurality of compute trays to cool compute resources within the compute tray; and upon determining one or more switch trays are operating to connect compute resources within the plurality of compute trays, increasing air flow through the one or more switch trays using an external fan bank comprising a plurality of fans directing air through a plenum positioned at a rear of the one or more switch trays.

In certain embodiments, the method further comprises increasing a flow rate of the air directed across the T-shaped heat sink bank within the compute tray based at least in part on a temperature increasing within the compute tray. In various embodiments, increasing a flow rate of the air flow through the one or more switch trays is based at least in part on a temperature increasing with the one or more switch trays. In certain embodiments, increasing a flow rate of air flow through the one or more switch trays comprises operating a subset of the plurality of fans of the external fan bank to direct air through the plenum positioned at the rear of the one or more switch trays. In various embodiments, directing air across the T-shaped heat sink bank within a compute tray comprises operating one or more fans positioned within an interior of the compute tray.

### BRIEF DESCRIPTION OF THE SEVERAL VIEWS OF THE DRAWINGS

For a better understanding of embodiments of the disclosure and to show how the same may be carried into effect, reference will now be made, purely by way of example, to the accompanying drawings in which like numerals designate corresponding elements or sections throughout. In the accompanying drawings:

FIG. 1 is an exploded view of a compute system in accordance with one embodiment;

FIG. 2 is a front view of a compute system in accordance with one embodiment;

FIG. 3A is a partial cutaway view of a compute tray in accordance with one embodiment;

FIG. 3B is a schematic showing connections among compute resources of a compute tray in accordance with one embodiment;

FIG. 4A is a partial cutaway view of a switch tray in accordance with one embodiment;

FIG. 4B is a view of a switch tray fan bank in accordance with one embodiment;

FIG. 5 is a rear view of a compute system in accordance with one embodiment;

FIG. 6 is a flowchart showing example operation of an air cooling system according to one embodiment;

FIG. 7 illustrates an example computer system that may include electrical components, according to at least one embodiment;

FIG. 8 provides a block diagram that schematically illustrates a computing system that may include one or more electrical components of various embodiments;

FIG. 9 illustrates an example computing environment that may include electrical components, in accordance with at least one embodiment;

FIG. 10 illustrates an example network environment according to at least one embodiment;

FIG. 11 illustrates an example data center environment according to at least one embodiment;

FIG. 12 illustrates infrastructure of a data center environment according to at least one embodiment; and

FIG. 13 illustrates an example liquid cooling system according to certain embodiments.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

As computing resources in compute trays and switch trays (e.g., optical switch trays, such as Co-Packaged Optics (CPO) switches of an NVSwitch that provides high-speed NVLink interfaces between compute resources of one or more compute trays) become more powerful and densely packaged, they generate more heat that must be directed away from those computing resources to maintain high processing capabilities. “Co-packaging,” as in a co-packaged optics switch, may refer to the close integration of different electrical and/or optoelectronic chips in the same package.

These compute resources may be installed and used in a data center, and these compute resources may be a source of heat generation within the data center. However, the open space around these compute resources has remained relatively steady or has decreased over time, thereby limiting the space available to remove for system and components to remove the heat generated by these compute resources. As the amount of space around these compute resources has decreased over time, the processing power density within data centers has increased, which consequently has increased the heat generation density in data centers. While different cooling mechanisms have been introduced and used in data centers over time, including various air-cooling systems and liquid cooling systems, prior cooling systems have many drawbacks, such as poor cooling efficiency and power consumption for air cooling systems or potential for damaging cooling fluid leaks for liquid cooling systems.

The cooling system described herein includes an air cooling system that increases cooling efficiency in part using an internal, compute tray cooling system and a switch tray cooling system. The cooling system described herein can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system.

For example, the air cooling capabilities may be correlated with the workload of a compute system performed by compute trays and switch trays, and by extension, can be correlated with an NVLink size domain within a compute system. While a compute system is operating under low workload conditions, the NVLink size domain may be small (e.g., without using NVSwitches embodied as switch trays), and cooling may be limited to cooling compute resources within individual compute trays. More specifically, the fan speed of a compute tray cooling system may be low for providing cooling air over a heat sink within the compute tray. The fan speed within the compute tray cooling system may increase as the workload performed by the compute tray increases. However, as the workload of the compute system increases to include tasks performed by one or more switch trays, thereby increasing the NVLink size domain using one or more NVSwitches (e.g., on the one or more switch trays), the amount of air cooling may increase to provide cooling to the switch trays utilized to increase the NVLink size domain. For example, where only a portion of the switch trays in a compute system are utilized to increase the NVLink size domain under moderate-to-high workload processing conditions, cooling may be provided to the compute trays and only to the subset of switch trays utilized. Moreover, the fan speed of the compute tray cooling system may further increase, as needed as the workload of the compute resources within the compute tray increases. The workload may be determined based on a detected temperature within the compute trays and/or switch trays, or using other mechanisms, such as data provided by the compute resources reflecting the current workload of the compute resources.

The NVLink size domain, as discussed herein, represents the level of interconnection between compute resources on multiple compute trays within a compute system. Interconnections between compute resources on multiple compute trays enable parallel processing of large and/or complex processing tasks using the multiple compute resources. Switchboards (e.g., NVLink switchboards) within switch trays provide the interconnections between compute resources on multiple compute trays, and these switchboards generate heat while providing interconnections between compute resources on multiple compute trays.

The level of cooling provided by the cooling system discussed herein may be correlated to the NVLink size domain (and consequently, to the workload performed by the compute trays and/or the switch trays) by increasing the amount of air flow through one or more trays (e.g., the compute trays and/or switch trays) of the compute system as the workload increases. At a low workload, the air cooling system may direct air through only one or more compute trays and over a heat sink bank using internal fans operating at a low rotational speed. As the workload increases, the fan speed of the internal fans of the compute trays may increase to maintain correlation between the workload and the level of cooling. As the workload further increases and is performed in part by one or more switch trays, the cooling further increases by operating one or more fans of an external fan bank to increase air flow through the switch trays. As the workload increases even further, the fan speed of the one or more fans of the external fan bank may increase and/or additional fans of the external fan bank may be operated to flow air through additional switch trays, as needed.

By extension, as the workload decreases (e.g., such that one or more switch trays are no longer performing any of the workload), the fans of the external fan bank that are associated with one or more switch trays may slow and/or turn off (according to control signals provided by a controller, for example). As the workload continues to decrease, the fan speed of internal fans within one or more compute trays may decrease so that the amount of cooling provided remains correlated with the workload of the compute system.

The compute tray cooling system includes a T-shaped heat sink bank proximate computing resources within each compute tray of a computing system. The T-shaped heat sink banks are cooled with air blown from a plurality of internal fans placed within each compute tray to cool the computing resources within each compute tray. The internal cooling system is present in a plurality of compute trays, thereby providing a cascaded and serviceable compute tray cooling system. The compute tray cooling system operates in tandem with an external fan bank positioned to cool switch trays within the same rack as the compute trays. The external fan bank includes fans that can be selectively operated (based at least in part on signals from a controller) depending on the compute resources used. During periods of minimal compute resource usage, the switch tray temperatures remain relatively low and cooling from the external fan bank may be unnecessary—the cooling provided by the internal cooling system in each of the plurality of compute trays is sufficient to maintain an appropriately cool operating temperature for the compute resources. During higher compute resource usage (when compute resources of the switch trays are used to connect compute resources in multiple compute trays), the external fan banks are utilized to provide additional air cooling for the switch trays. Those external fan banks comprise high-pressure fans positioned at a rear of the switch trays and with a plenum to direct air flow through the switch trays when the fans are active.

The external fan bank comprises a plurality of external fans. These may be individually operated, or operated as one or more groups of fans (e.g., each group comprising a subset of the total number of fans, or the group comprising all of the fans). The external fan banks may be controlled with a controller. In some embodiments, the controller comprises a stand-alone computing resource. The controller may also comprise one or more of the compute tray computing resources, and may utilize a standalone controller as a backup controller in the event that one or more computing resources in the compute trays fail. The external fan bank may also be expandable to accommodate different sizes of switch trays and/or to accommodate different quantities of switch trays within a stack. The fans of the external fan bank may be active to provide cooling as needed, based at least in part on the workload of the compute system and the NVLink size domain.

### System Components

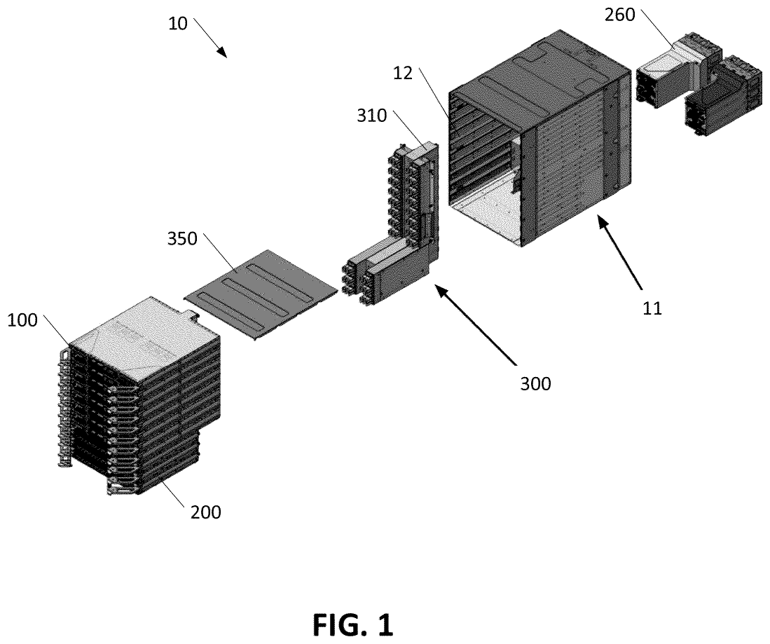

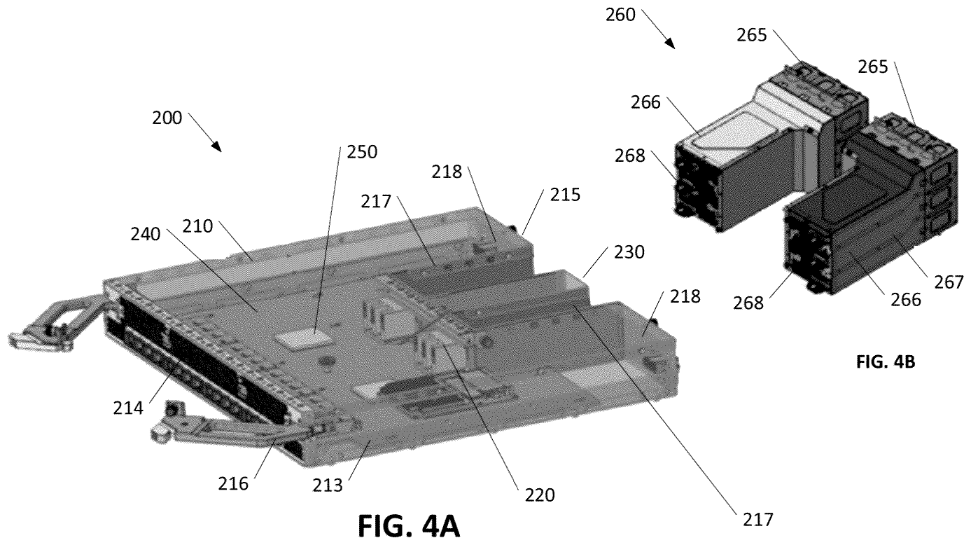

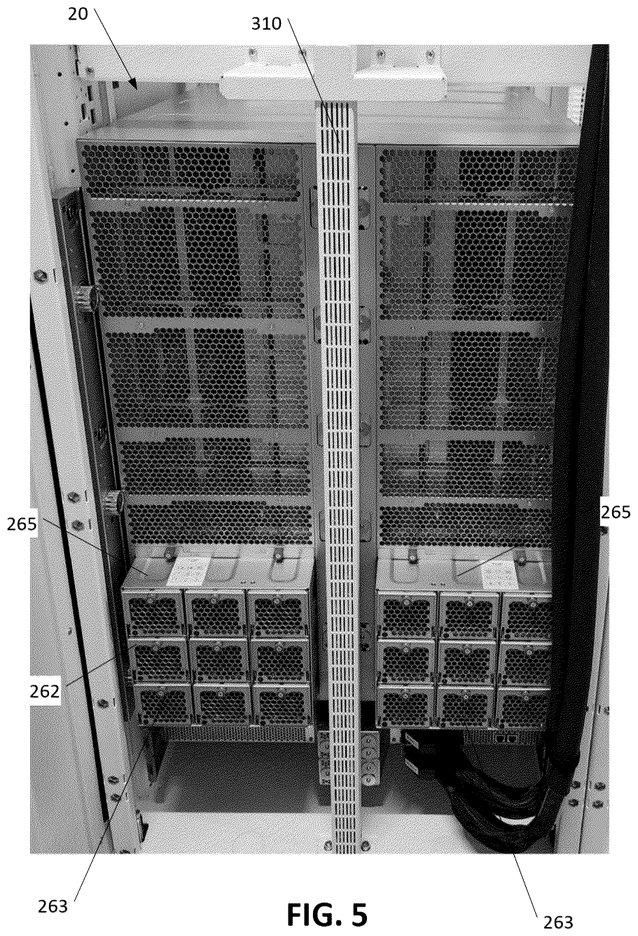

FIG. 1 is an exploded view of a compute system 10 incorporating a cooling system 20 (denoted in FIG. 4A-4B), that may form a part of a data center comprising a plurality of compute systems 10 connected together. The compute system 10 comprises a plurality of compute trays 100 and a plurality of switch trays 200 (e.g., NVSwitch trays). As shown, the compute system 10 includes 8 compute trays 100 and 3 switch trays 200, with all of the compute trays 100 grouped together and all of the switch trays 200 grouped together. However, it should be understood that other quantities of compute trays 100 and switch trays 200 may be provided in certain embodiments. The cooling system 20 as discussed herein comprises at least a compute tray cooling system 22 and a switch tray cooling system embodied by one or more external fan banks 260.

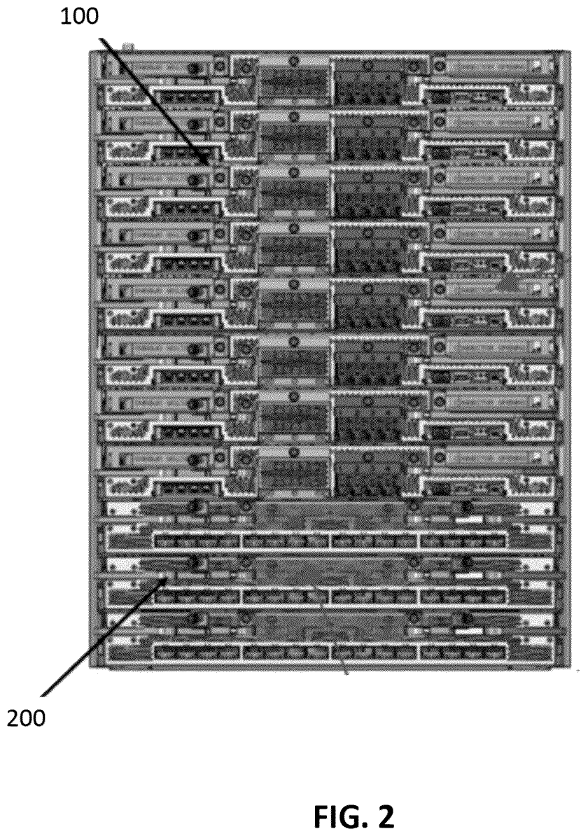

As shown in FIG. 2, the compute trays 100 and switch trays 200 are arranged in a vertical stack within the compute system 10, with the compute trays 100 located above the switch trays 200. In some embodiments, a divider 350 is provided between the compute trays 100 and switch trays 200. As discussed herein, each compute tray 100 and each switch tray 200 is secured within a system housing 11 using slides on lateral sides of the compute trays 100 and switch trays 200, such that the weight of the compute trays 100 and switch trays 200 are supported by the system housing 11.

The compute trays 100 and switch trays 200 are attached at a back side to a cable cartridge 300, which comprises an open interior for routing cables between the compute trays 100 and switch trays 200, and comprises a bus bar 310 for providing power to each of the compute trays 100 and server trays 200. The bus bar 310 may be connected to an external power source, and may be connected to one or more power connectors for each of the compute trays 100 and switch trays 200 to provide power to the components included in the respective trays. Certain of those components are discussed in detail in the following subsections.

As shown in FIG. 1, the compute trays 100, switch trays 200, and cable cartridge 300 are mechanically secured within a housing 11 that includes slides to enable individual trays to be removed (e.g., for service and/or replacement). In some embodiments, the housing 11 may be a server rack. In some embodiments, the housing 11 has closed sides (as shown), although it should be understood that some embodiments may have open sides, with supports for the trays defined by a chassis and/or rails. In some embodiments, the housing 11, rails 12, and/or cable cartridge 300 may be Electronic Industries Alliance (EIA) standards compliant, with a bus bar 310 that is Open Rack Version 3 (ORV3) standards compliant.

As discussed in greater detail herein, the compute trays 100 each comprise a plurality of compute resources 150 and the plurality of compute resources 150 are grouped into groups of compute resources 150. The compute resources 150 within a group of compute resources 150 are in communication with one another. The groups of compute resources 150 are selectively in communication with one another using an on-tray communication bridge 153 configured to control communication between groups of compute resources hosted by a single compute tray 100. As discussed herein, each compute tray 100 comprises cooling components, including fans and a heat sink bank that collectively function to provide adequate air cooling to cool the compute resources based on their respective workload as they perform processing tasks. The amount of cooling provided by the cooling components may be adjusted depending on the workload of compute resources 150 to perform the processing task.

In various embodiments, the on-tray communication bridge 153 defines one or more L1 domains of the tray and/or connects the one or more L1 domains of a single compute tray 100 with L2 domains or aggregation layers that aggregate traffic from a plurality of L1 domains to perform functions such as load balancing. For example, the on-tray communication bridge, either via a dynamically configurable communication topology or a fixed communication topology, is configured to define, at any one point in time, a plurality of L1 domains on the tray that each include a single group of compute resources, two or more L1 domains on the tray that each include a subset of the plurality of groups of compute resources, or a single L1 domain on the tray that includes all of the groups of compute resources hosted by the tray. In some embodiments, the compute resources within an L1 domain may be sufficient to perform a workload sufficient to execute certain processing tasks. For more complex processing tasks characterized by a higher workload of the compute system 10, the switch trays 200 (connected with a plurality of compute trays 100) are utilized to define a configurable L2 domain to aggregate compute resources to perform the more complex processing task. Some data centers may also include an L3 domain configured to route traffic between various L2 domains and communicate with networks external to the data center.

As shown, a data center (or a compute system 10) includes switch trays 200 that are configurable to control operation of the various L1 domains on a single compute tray 100 and/or to connect multiple L1 domains of multiple compute trays 100 according to an L2 domain.

A compute system 10 may include multiple network switches (embodied on switch trays 200) in a particular topology, such as a fat tree topology, a slim fly topology, a dragonfly topology, and/or the like. The specifications and makeup of the network switches in the topology affects the overall network performance (e.g., bandwidth capability) of a data center encompassing a plurality of compute systems 10.

Data centers are the storage and data processing hubs of the internet. The massive deployment of cloud applications is causing data centers to expand exponentially in size, stimulating the development of faster switches than can cope with the increasing data traffic inside the data center. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

As discussed in greater detail herein, the compute system 10 comprises one or more external fan banks 260 collectively embodying a switch tray cooling system insertable into the housing 11 at the backside of the stack of switch trays 200. The illustrated embodiment comprises two fan banks 260, to be inserted on opposite sides of the bus bar 310 and extend to the backside of the switch trays 200. The fan banks 260 of the illustrated embodiment have sliding features (discussed below) for interacting with the rails 12 of the housing 11 and for securing the fan banks 260 in the housing 11. The external fan banks 260 are electrically connected to a power source, such as the bus bar 310. The external fan banks 260 may also be connected to a controller for controlling operation of the external fan banks 260 based at least in part on operation of the compute trays 100, the switch trays 200, and/or temperature sensors incorporated in the compute trays 100 and/or the switch trays 200. In some embodiments, the controller is one or more of the compute trays 100.

As discussed herein, the controller (whether embodied as a part of the compute trays and/or a standalone controller for the external fan bank) is configured to selectively operate one or more high pressure fans of the external fan bank as needed, depending on operation of the switch trays 200 and the temperature thereof.

### Compute Tray

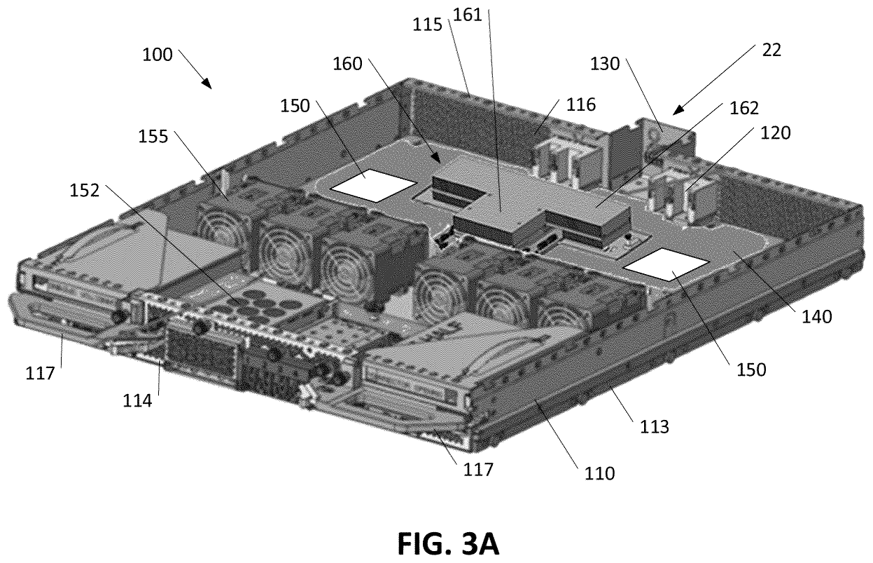

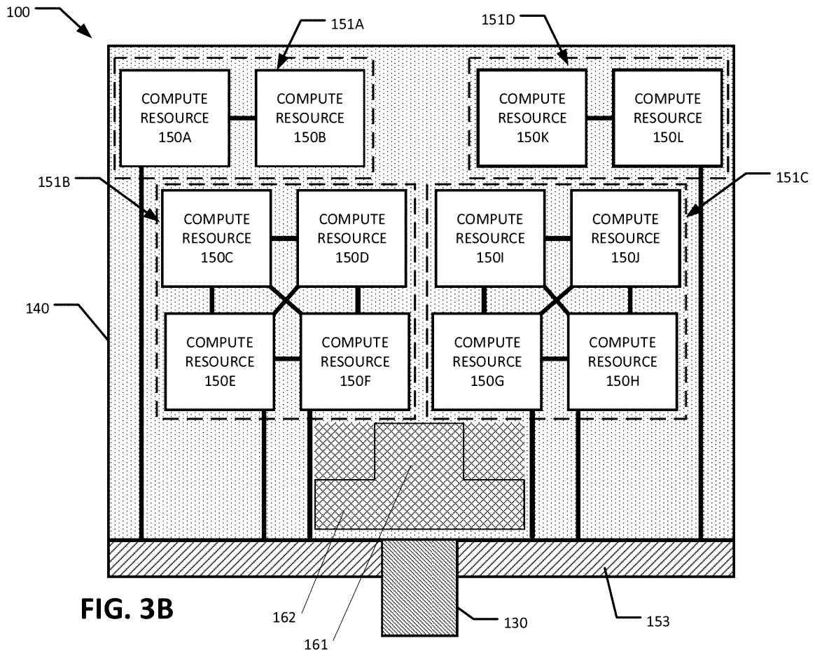

FIG. 3A illustrates components of a compute tray cooling system 22 that is a part of a compute tray 100. The compute tray cooling system 22 includes a serviceable heat sink bank 160 according to certain embodiments. As shown, the compute tray 100 comprises a housing 110 having slide components 113 that interact with the rails 12 of the system housing 11 to support the compute tray 100 at a vertical location within the system housing 11 and to enable the compute tray 100 to be easily removed from the system housing 11 for maintenance and/or replacement. As shown in FIG. 3A, the compute tray housing 110 further comprises lever-style handles 117 that include mechanical locking components to mechanically secure the compute trays 100 into the system housing 11 by locking into interacting locking components of the system housing 11.

As shown, the housing 110 defines a front wall 114 and an opposite back wall 115. The back wall 115 defines vents 116 to allow air to pass into and out of the interior of the housing 110. At the back wall 115, the compute tray 100 additionally comprises cable connectors 120 for connecting with cables that run through the cable cartridge 300 and a bus bar connector 130 for connecting power supplies of the compute tray 100 with the bus bar 310 of the system 10. As discussed herein, the cable connectors 120 and bus bar connectors 130 are compliant with EIA and/or ORV3 standards (or other relevant standards).

Inside the compute tray 100, a substrate 140 (e.g., a Printed Circuit Board (“PCB”)) supports one or more compute resources 150. As shown in FIG. 3B, those compute resources 150 (including example compute resources 150A-150L) may be organized in a plurality of groupings of compute resources 151 (e.g., 151A-151D). The compute tray 100 also includes an on-tray communication bridge 153 configured to provide communication links between selected pairs of groupings of compute resources 151, for example, as processing tasks are characterized by higher workloads requiring additional processing resources for completion. For example, each grouping of compute resources 1512 may be configured to be operated as an individual L1 domain or may be combined with other groupings of compute resources hosted by the compute tray 100 to provide a larger L1 domain. In some embodiments, the combining of a selected pair of groupings of compute resources 151 is accomplished via communication links between the selected pair of groupings of compute resources 151 provided by the on-tray communications bridge 153. For example, the on-tray communication bridge 153 may be configured to control communication between the plurality of groupings of compute resources 151 to provide a configurable number of L1 domains on the tray 100.

The compute resources 150 may be embodied as one or more compute resources 150 (e.g., 150A-150L). In various embodiments, the plurality of compute resources 150 hosted by a tray may include one or more of CPUs, PPUs, GPUs, DPUs, QPUs, and/or other processing units. The plurality of compute resources 150 are organized and/or configured as a plurality of groups 151 (e.g., 151A-151D). For example, a grouping of compute resources 150 is a group 151 of compute resources 150, in various embodiments.

In certain embodiments, the on-tray communications bridge 153 is further configured to connect the compute resources 150 of the compute tray 100 with compute resources 150 in other compute trays 100 within a server rack. Accordingly, the communications bridge 153 comprises one or more appropriate connectors (e.g., optical connectors) for providing off-tray connections. As discussed herein, those off-tray connections are provided in part using switch trays 200, which provide load balancing and connections among a plurality of compute trays 100 using switchboards that pass data signals between compute trays 100. For low workload processing tasks, the compute resources 150 of a single compute tray 100 may be adequate to complete the processing tasks. However, for larger workload processing tasks, additional compute resources 150 are utilized, requiring connections among the plurality of compute trays 100 using the switch trays 200. As those switch trays 200 are utilized, the switch trays 200 generate heat, requiring additional cooling beyond the cooling components within any individual compute tray 100.

As shown in FIG. 3A, the compute tray 100 comprises an internal fan bank comprising plurality of fans 155 disposed in a row across the width of the substate 140. In the illustrated embodiment, the internal fan bank comprises 6 fans, although it should be understood that other numbers of fans are possible in various embodiments. The plurality of fans of the internal fan bank is positioned in a line across a width of the substrate 140 and between the compute resources 150 and power components 152 of the compute tray 100. In the illustrated embodiment, the compute resources 150 are located proximate a rear of the compute tray 100, and the power components 152 are located proximate a front of the compute tray 100. Accordingly, the compute resources 150 are positioned between the internal fan bank and the backside of the compute tray 100.

In the illustrated embodiment of FIGS. 3A-3B, the compute tray 100 additionally comprises a serviceable heat sink bank 160. The heat sink bank 160 comprises a heat-conductive material secured onto the surface of the substrate 140. The heat sink bank 160 comprises one or more banks of fins extending away from the substrate 140. The one or more banks of fins may comprise rectangular plate fins, trapezoidal fins, square plate fins, circular plate fins, and/or other fin shapes. The fins may be bonded, forged, extruded, stamped, folded, skived, or formed through any of a variety of heat sink forming techniques. The heat sink bank has a height, measured from the substrate surface that is less than the distance between the substrate surface and a top cover of the compute tray 100.

The banks of fins of the heat sink bank 160 collectively have a T-shape, comprising a central portion 161 that extends between the plurality of computing resources 150 and outrigger portions 162 on opposite sides of the central portion 161. Collectively, the central portion 161 and outrigger portions 162 fill portions of the surface of the substrate that are not occupied by compute resources 150 (some of which are shown schematically in FIG. 3A) to provide a high-degree of cooling for the compute resources 150. In some embodiments, portions of the heat sink bank are positioned between the computing resources 150 and the back wall 115 of the compute tray 100.

In use, the internal fan bank 155 directs air over the compute resources and through the heat sink bank 160 to dissipate heat from the substrate (heated from the compute resources 150 and/or the power components 152) and thereby cool the interior of the compute tray 100. Air flow through the compute trays 100 (directed by the internal fan bank 155) pull air from a cold side of the compute tray 100 and exhaust air to a hot side of the compute tray 100. When the compute system 10 is positioned in a data center, the data center may have air flow systems at the hot side of the compute tray 100 (which may also be the hot side of other compute trays 100 in other housings 11 in the data center) to remove air from the hot side of the compute tray 100. Similarly, the data center may have air flow system to maintain cold air at the cold side of the compute tray 100.

Operation of the internal fan bank 155 is controlled by a controller. The controller may be embodied as one of the compute resources 150 of the compute tray 100 (the compute resource 150 of a plurality of compute resources 150 may be dedicated to operating the internal fan bank 155, or the compute resource 150 may operate the internal fan bank 155 as a part of more general processing tasks). In some embodiments, operation of the internal fan bank 155 is controlled by a controller external to the compute tray 100. For example, a controller operating internal fan banks 155 of a plurality of compute trays 100 and/or operating external fan banks 260 for one or more switch trays 200 (as discussed herein) may provide control for the internal fan bank 155. Control of the internal fan bank 155 may comprise turning the fans of the internal fan bank 155 on/off (either individually or as a group) and/or controlling the rotational speed of the fans of the internal fan bank 155 (either individually or as a group). Control operations, including turning fans on/off and/or changing the rotational speed of fans, may be performed based at least in part on one or more operational characteristics of the compute tray(s) 100 and/or the switch trays 200. These operational characteristics may comprise the workload performed (or amount of processing power) by the compute resources 150 of a compute tray 100 to perform processing tasks at a given time and/or one or more temperature readings provided by one or more temperature sensors within the compute tray 100. For example, as processing demands on the compute tray 100 increase and the compute tray 100 utilizes increasing processing power of the compute resources 150, the rotational speed of fans in the internal fan bank 155 may be increased to increase air flow. Operation of the internal fan banks 155 of a plurality of compute trays 100 may be cascaded based on processing tasks executed by a plurality of compute trays 100. For example, the fan speed of the internal fan banks 155 may be increased as the workload performed by the processing resources 150 within the compute tray 100 increases. The cascaded operation of the internal fan banks 155 blowing air across the heat sink banks may be provided in tandem with operation of external fan banks for cooling the switch trays as discussed herein, such that only those compute resources and switch trays involved in a processing task are cooled. This provides a correlation between the amount of air cooling performed by the air cooling system and the NVLink size domain operating within the compute system 10 (and by extension, provides a correlation between the total workload performed by the compute system 10 and the cooling provided by the air cooling system). As another example, as temperature sensors within the compute tray 100 provide increasing temperature readings, the rotational speed of fans in the internal fan bank 155 can be increased. It should be understood that other operational characteristics may be utilized as a part of controlling the operation of the internal fan bank 155.

When operating with the switch tray cooling system described herein, the compute tray cooling system 22 provides adjustable cooling that correlates the amount of cooling provided by the compute tray cooling system 22 with the workload performed by the compute system, while the workload is executed by the compute resources within a single compute tray by varying the fan speed of the internal fan bank 155. As the workload increases to involve switch trays and/or additional compute trays (thereby increasing the NVLink size domain), the switch tray cooling system provides further cooling to correlate the amount of cooling provided by the air cooling system with the workload of the compute system.

### Switch Tray

A switch tray 200 as discussed herein may be embodied as an NVSwitch tray comprising one or more NVSwitch chips that connects multiple compute resources (e.g., GPUs) with high-speed NVLink interfaces. The NVSwitch chip of an NVSwitch tray may comprise a plurality (e.g., 64) NVLink ports for connecting a plurality of compute resources into a large fabric network that provides connections among L1 domains of multiple compute trays 100 as needed to execute processing tasks.

FIG. 4A illustrates components of a switch tray 200 according to certain embodiments, and FIG. 4B illustrates a fan bank 260 according to certain embodiments. When positioned within the housing 11, the fan bank 260 abuts a backside of the switch tray 200 (among a stack of a plurality of switch trays 200), to flow air through the switch tray 200.

As shown in FIG. 4A, the switch tray 200 comprises a housing 210 having slide components 213 that interact with the rails 12 of the system housing 11 to support the switch tray 200 at a vertical location within the system housing 11 and to enable the switch tray 200 to be easily removed from the system housing 11 for maintenance and/or replacement. As shown in FIG. 4A, the switch tray housing 210 further comprises lever-style handles 216 that include mechanical locking components to mechanically secure the switch trays 200 into the system housing 11 by locking into interacting locking components of the system housing 11.

As shown, the housing 210 defines a front wall 214 and an opposite back wall 215. The front wall 214 and the back wall 215 are vented (vents shown at 218) to allow air to pass into and out of the interior of the housing 210. At the back wall 215, the switch tray 200 additionally comprises cable connectors 220 for connecting with cables that run through the cable cartridge 300 and a bus bar connector 230 for connecting power supplies of the switch tray 200 with the bus bar 310 of the system 10. In the illustrated embodiment, the back wall 215 defines slots 217 extending into the interior of the switch tray housing 210, and the cable connectors 220 are disposed at interior ends of the slots 217. The slots 217 are positioned on opposite sides of the bus bar connector 230.

Inside the switch tray 200, a substrate 240 (e.g., a PCB) supports one or more compute resources 250. The compute resources 250 (e.g., optical switchboards, such as NVSwitch chips) and the switch tray 200 may be embodied as a CPO switch tray, and the substrate 240 supports a plurality of optical connectors and/or optical interconnects (e.g., optical fibers) that optically connect the compute resources 250 with connects (e.g., on a front wall 214 of the switch tray 200).

In certain embodiments, where the switch trays 200 are positioned in the housing 11, an external fan bank 260 comprising a plurality of external fans 263 are positioned at a rear of the housing 11. The external fan bank 260 comprises a plurality of fans 263 each within individual fan housings 262 that are connected together by a fan assembly housing 265 and/or using fasteners, using connection features on the exterior of the individual fan housings 262 and/or the like. In the illustrated embodiment, the external fan bank comprises a 2-dimensional array of fans in individual fan housings 262 that are secured together within a fan assembly housing 265 such that the individual fan housings 262 are aligned. For example, the individual fan housings 262 are aligned such that a rear wall of the individual fan housings 262 (visible in FIG. 5) define a common plane (embodied as a surface of the fans). As shown, the external fan bank comprises 9 fans, arranged in a 3×3 array of fans and the fan assembly housing encircles the 2-dimensional array. The external fan bank (and the fan assembly housing) as shown is sized and configured for cooling a stack of 3 switch trays 200.

The external fan bank 260 of certain embodiments is modular, such as the size of the external fan bank 260 can be changed by adding or removing fans (e.g., adding or removing a row of fans, such as 3 fans, collectively having a width set to fit within a standard system housing 11). In some embodiments, the fans of the external fan bank 260 have a height that matches a height of the switch tray 200, such that a single row of fans within the external fan bank 260 provides air flow to the interior of the switch tray 200. However, it should be understood that the fans may have different dimensions (e.g., height) as compared with the switch tray 200 in some embodiments.

In some embodiments, a subset of fans within the external fan bank (e.g., a single row of fans in the external fan bank) may be assigned to a particular switch tray 200, to provide cooling to that switch tray 200. As the assigned switch tray 200 is active, the subset of fans within the external fan bank are active to provide cooling to the active switch tray 200. As the workload performed by the compute system 10 increases and additional switch trays 200 become active, additional subsets of fans of the external fan bank 260 may be activated to correlate the amount of cooling provided with the increased NVLink size domain.

As fans are added/removed from the external fan bank 260, the fan assembly housing 265 may be resized or replaced to accommodate the different size of the external fan bank 260, and/or the fans of the external fan bank 260 may be connected related to one another (e.g., with fasteners or connection features on the individual fan housings 262). As discussed in greater detail herein, a plenum 266 may be resized and/or replaced to accommodate the different size of external fan bank 260.

As shown, the external fan bank 260 comprises a plenum 266 that attaches at a face of the plurality of fans 263 and extends to a distal end 268 that, when positioned within the housing 11, is positioned adjacent with the back wall 215 of the switch trays 200. For example, the distal end 268 of the plenum 266 may is adjacent to the back wall 215 of the switch trays 200 when the distal end 268 of the plenum 266 is in contact with the back wall 215 of the switch trays 200 and/or when the distal end 268 of the plenum 266 is sufficiently close to the back wall 215 of the switch trays 200 to direct all or nearly all of the air moved by the plurality of fans through the plenum 266 into the interior of the switch trays 200 through the vented back wall 215 of the switch trays 200. The plenum 266 is shaped to contour around the bus bar 310 and within the housing 10. In certain embodiments, the plenum may comprise slides 267 to secure the plenum 266 within the housing 11 using rails 12. Like the external fan bank 260, the plenum 266 may be modular, such that the size of the plenum 266 may be increased/decreased by attaching or detaching plenum components relative to one another. Each plenum component, in some embodiments, may be sized and configured to accommodate air flow from a single row of fans within the external fan bank 260. Each plenum component may have enclosed side walls and top/bottom walls, and may be connectable relative to other plenum components to form a plenum 266 sized appropriately for the size of the external fan bank 260 (and sized appropriately to accommodate the total number of switch trays 200 within a switch tray stack).

As shown, a plurality (e.g., 2) of external fan banks 260 may be provided, on opposite sides of the bus bar 310. Each of the plurality of external fan banks 260 may have the same configuration as one another (e.g., size, shape, number of fans, and/or the like). The plenums 266 on opposite sides of the bus bar 310 may be mirrored relative to one another to flow air around opposite sides of the bus bar 310.

The external fan banks 260 each comprise a power connector that may be secured to the bus bar 310 to enable power of the external fan banks. The external fan banks may be controlled by a controller (e.g., the same controller operating the internal fan banks 155 of the compute trays 100). Accordingly, the external fan banks 260 may comprise a controller connection to receive control signals from an external controller (e.g., a compute resource 150 in a compute tray 100 that controls the operation of the internal fan banks 155 and external fan banks 260. The external fan banks 260 may be controlled to increase fan speeds as the compute trays 200 are used, or to decrease (or turn off) the fan speeds if the compute trays 200 are unused or if the compute trays 200 are generating negligible heat. Such controlling of the external fan banks 260 optimize power consumption versus cooling of the switch trays 200. This control scheme operates the external fan banks 260 in tandem with the internal fan banks 155, such that an optimal amount of cooling is provided to the compute trays 100 and switch trays 200 collectively. Similar to the compute trays 100, the switch trays 200 may comprise one or more temperature sensors to provide information of the temperature within the switch trays 200. As the temperatures within the switch trays 200 increase, the external fan banks 260 may be utilized to increase air flow through the switch trays 200 to cool the compute resources 250 of the switch trays 200. In some embodiments, the controller controls the speed of the fans collectively, such that all of the fans spin at the same angular velocity. In other embodiments, the controller can individually adjust the fan speed of each fan 263 individually.

The external fan bank for the switch trays 200 works in tandem with the internal fan bank and heat sink of the compute trays 100. For example, if the collective compute power provided by the compute trays 100 and the switch trays 200 is low and compute tasks can be performed entirely with L1 connections between compute resources 150 within a single compute tray 100, the switch trays 200 may be unused for these compute tasks and the compute trays 200 therefore generate minimal heat that can be addressed without cooling by the external fan banks 260. In such an instance, the external fan banks 260 may be turned off, or may be operated at low fan speeds.

As more intensive compute tasks are performed by the system 10, the amount of data passed between compute trays 100 increases according to NVLink connections that allows for parallel processing among compute resources 150 of a plurality of compute trays 100. The switch trays 200 enable connections among the plurality of compute trays 100 and efficiently utilize available processing capacity among the plurality of compute resources 150 of the plurality of compute trays 100. Accordingly, the compute resources 250 of the switch trays 200 are utilized more heavily during intensive compute tasks, and the temperature of the switch trays 200 increases during use. During these intensive compute tasks, the external fan bank 260 may be activated and/or the rotational speed of the fans within the external fan bank 260 may be increased to increase air flow through the switch trays 200.

FIG. 5 is a rear view of a system, showing the positioning of a fan assembly according to certain embodiments. As shown, individual fans 263 within individual fan housings 262 are secured within a fan assembly housing 265, and the fan assembly housing 265 is secured within the housing 11.

### Example Use

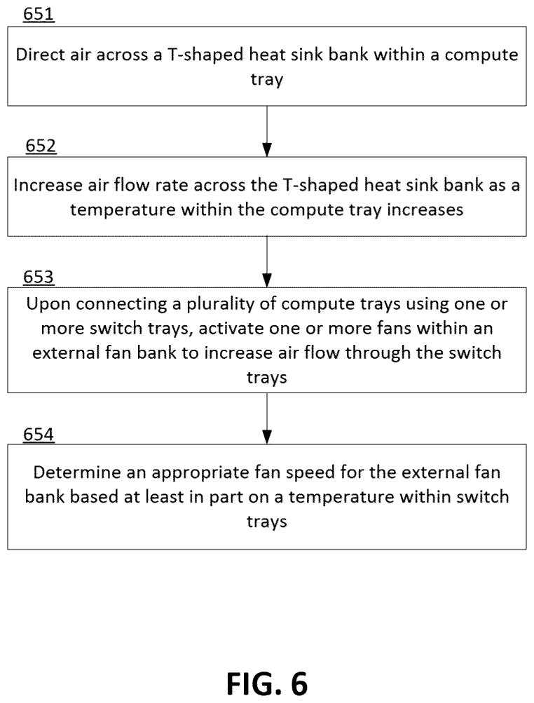

FIG. 6 is a flowchart showing example steps of a method of using a cooling system as discussed herein. As shown in block 651, air is directed across a T-shaped heat sink bank within a compute tray, for example, by one or more fans positioned within an interior of the compute tray. The air flow rate (and consequently, the fan speeds) are dictated by the amount of heat generated by the compute resources of the compute tray. In turn, the amount of heat generated by the compute resources is dependent on the workload expended by the compute resources. As shown in block 652, the air flow rate across the T-shaped heat sink bank within the compute tray may be increased based on a temperature within the compute tray (e.g., as determined by one or more sensors within the compute tray, or based on a measure of workload expended by the compute resources). By extension, the flow rate across the T-shaped heat sink bank can be decreased to conserve power during low-power processing tasks.

For high intensity processing tasks in which a plurality of compute trays are connected by switch trays (e.g., using NVSwitch chips) for load balancing and for task distribution, external fan banks may be activated to increase the air flow rate through the switch trays as the compute resources of the switch trays expel heat, as reflected in block 653. An appropriate fan speed for the fans of the external fan bank may be determined at block 654. One or more of the steps shown in FIG. 6 may be repeated as needed, as the workload performed by the compute resources of the compute trays and switch trays changes over time.

### Computer System

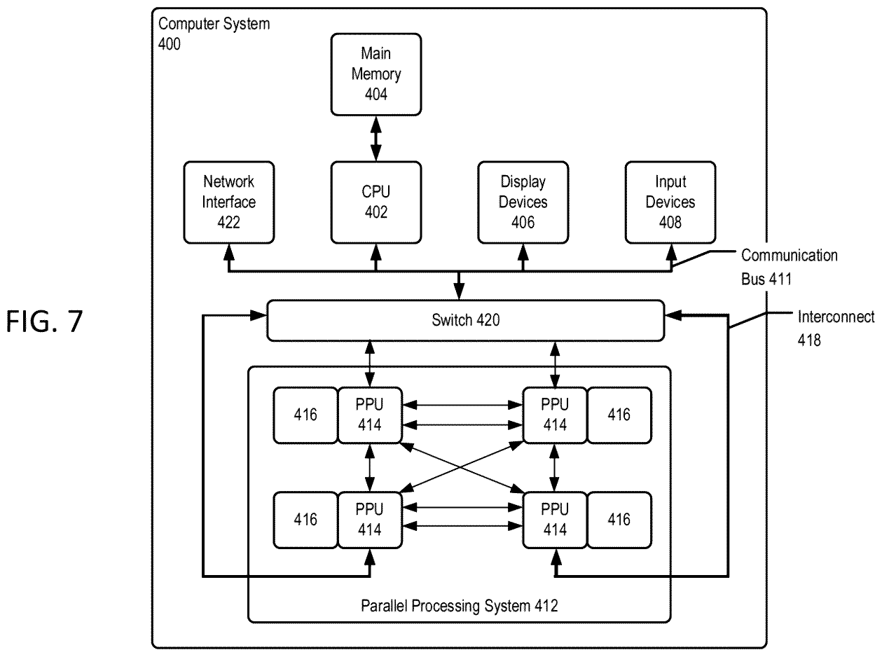

FIG. 7 illustrates a computer system 400, according to at least one embodiment. In at least one embodiment, computer system 400 is configured to implement various processes and methods described throughout this disclosure.

In at least one embodiment, computer system 400 comprises, without limitation, at least one central processing unit (“CPU”) 402 that is connected to a communication bus 410 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 400 includes, without limitation, a main memory 404 and control logic (e.g., implemented as hardware, software, or a combination thereof) and data are stored in main memory 404 which may take form of random access memory (“RAM”). In at least one embodiment, a network interface subsystem (“network interface”) 422 provides an interface to other computing devices and networks for receiving data from and transmitting data to other systems from computer system 400.

In at least one embodiment, computer system 400, in at least one embodiment, includes, without limitation, input devices 408, parallel processing system 412, and display devices 406 which can be implemented using a conventional cathode ray tube (“CRT”), liquid crystal display (“LCD”), light emitting diode (“LED”), plasma display, or other suitable display technologies. In at least one embodiment, user input is received from input devices 408 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 404 and/or secondary storage. Computer programs, if executed by one or more processors, enable system 400 to perform various functions in accordance with at least one embodiment. memory 404, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 402; parallel processing system 412; an integrated circuit capable of at least a portion of capabilities of both CPU 402; parallel processing system 412; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 400 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 412 includes, without limitation, a plurality of parallel processing units (“PPUs”) 414 and associated memories 416. In at least one embodiment, PPUs 414 are connected to a host processor or other peripheral devices via an interconnect 418 and a switch 420 or multiplexer. In at least one embodiment, parallel processing system 412 distributes computational tasks across PPUs 414 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 414, although such shared memory may incur performance penalties relative to use of local memory and registers resident to a PPU 414. In at least one embodiment, operation of PPUs 414 is synchronized through use of a command such as_syncthreads( ), wherein all threads in a block (e.g., executed across multiple PPUs 414) to reach a certain point of execution of code before proceeding.

The switches within each layer (e.g., edge layer, aggregation layer, core layer) may be 1 U switches, where “1 U” refers to the industry-standard size for rack-mounted switches and servers. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

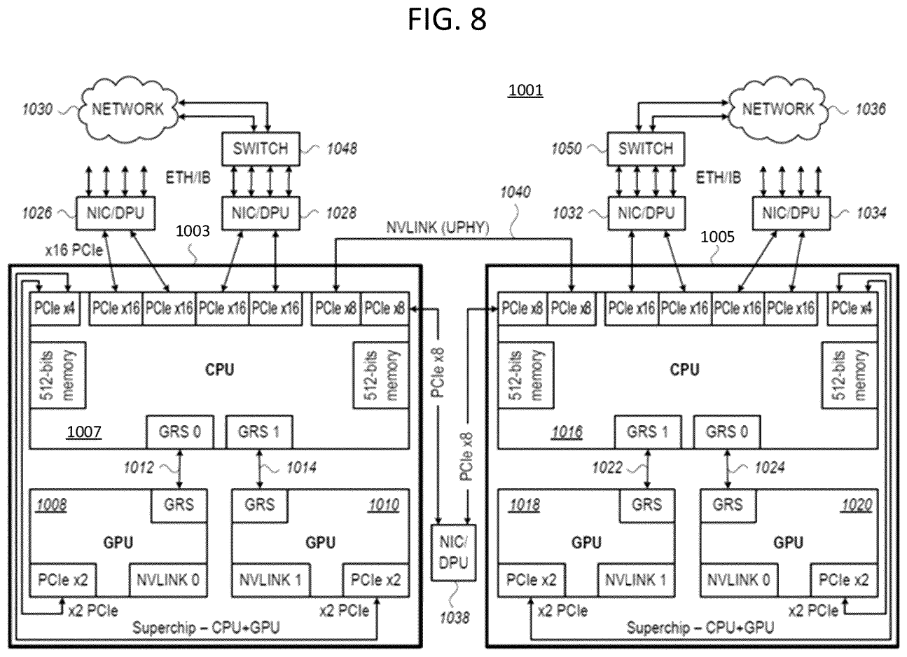

FIG. 8 is a block diagram that schematically illustrates a computing system 1001, e.g., a data center or a High-Performance Computing (HPC) cluster, in accordance with an embodiment that is described herein. System 1001 comprises a plurality of subsystems, e.g. multiple processing devices coupled to each other, multiple network devices, and multiple networks, according to at least one embodiment. Computing system 1001 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1001 and to one or more external networks 1030, 1036. In the present example, system 1001 comprises a packet switch 1048 that connects NIC/DPU 1028 to network 1030, and a packet switch 1050 that connects NIC/DPU 1032 to network 1036.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1001 can include one or more CPUs and one or more GPUs, data processing units (DPUs), quantum processing units (QPUs), a plurality of parallel processing units (PPUs), and application-specific integrated circuits (ASICs). QPUs configured to perform one or more operations associated with a quantum algorithm In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

FIG. 8 also demonstrates an example architecture of a multi-GPU architecture. As illustrated in the figure, computing system 1001 includes a processing device 1003 with a multi-GPU architecture. In particular, processing device 1003 may be a system-on-chip and includes multiple subsystems such as a CPU 1007, a GPU 1008, and a GPU 1010. CPU 1007 can be coupled to GPU 1008 via a die-to-die (D2D) or chip-to-chip (C2C) interconnect 1012, such as a Ground-Referenced Signaling interconnect (GRS interconnect). CPU 1007 can be coupled to GPU 1010 via a D2D or C2C interconnect 1014. CPU 1007 can also couple to GPU 1008 and GPU 1010 via PCIe interconnects.

CPU 1007 can be coupled to one or more NICs or DPUs, which are coupled to one or more networks. For example, as illustrated in FIG. 8, CPU 1007 is coupled to a first NIC/DPU 1026, which is coupled to a network 1030. CPU 1007 is also coupled to a second NIC/DPU 1028, which is coupled to network 1030 via switch 1048. NIC/DPU 1026 and NIC/DPU 1028 can be coupled to network 1030 over Ethernet (ETH), NVLINK or InfiniBand (IB) connections, for example.

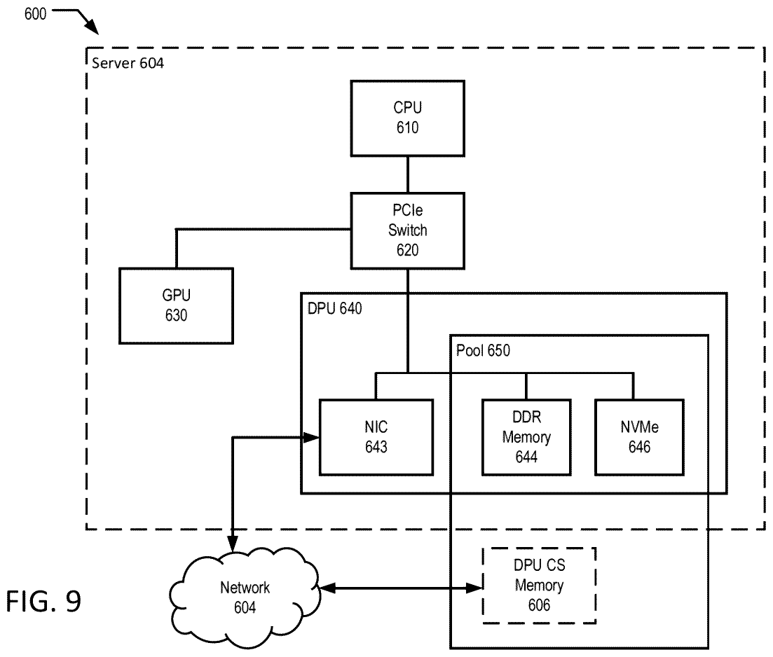

Computing system 1001 also includes a processing device 1005 with a multi-GPU architecture. In particular, processing device 1005 includes multiple subsystems including a CPU 1016, a GPU 1018, and a GPU 1020. CPU 1016 can be coupled to GPU 1018 via an D2D or C2C interconnect 1022. CPU 1016 can be coupled to GPU 1020 via a D2D or C2C interconnect 1024. CPU 1016 can also couple to GPU 1018 and GPU 1020 via PCIe interconnects. CPU 1016 can be coupled to one or more NICs or DPUs, which are coupled to one or more networks. For example, as illustrated in FIG. 9, CPU 1016 is coupled to a first NIC/DPU 1032, which is coupled to a network 1036. CPU 1016 is also coupled to a second NIC/DPU 1034, which is coupled to network 1036 via switch 1050. NIC/DPU 1032 and NIC/DPU 1034 can be coupled to network 1036 over Ethernet (ETH), NVLINK or InfiniBand (IB) connections.

In at least one embodiment, processing device 1003 and processing device 1005 can communication with each other via a NIC/DPU 1038, such as over PCIe interconnects. Processing device 1003 and processing device 1005 can also communicate with each other over a high-bandwidth communication interconnects 1040, such as an NVLink interconnect or other high-speed interconnects. The packet switches in FIG. 8 may comprise, for example, Nvidia Quantum-2 switches. The NICs/DPUs in the figure may comprise, for example, Nvidia Bluefield DPUs.

In various embodiments, any of the network devices of system 1001, e.g., any of NICs/DPUs 1026, 1028, 1032, 1034, and 1038, and/or any of switches 1048 and 1050, may include electrical components in accordance with various embodiments.

FIG. 9 illustrates an example computing environment 600 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 600 may include a server 602 which may be used to perform HPC workloads, such as AI training or machine learning model training. In an embodiment, the server 602 may be an application instance or a compute node. The server 602 may include a CPU 610 associated with a switch 620, such as a peripheral component interconnect express (PCIe) switch, which may control at least some data transmission over communication paths interconnecting various components. In an embodiment, the CPU 610 may include a root complex processor.

The PCIe switch 620 may also be associated with a GPU 630 and a DPU 640, and may transmit data between at least some of the CPU 610, the GPU 630, the DPU 640, and other components. In an embodiment, the PCIe switch 620 may be associated with more than one GPU or more than one DPU. In another embodiment, the PCIe switch 620 may be located within the DPU 640. The PCIe switch 620 may manage the transfer of at least some data between the CPU 610, the GPU 630, and the DPU 640. In another embodiment, the number of GPUs associated with the PCIe switch 620 may be equal to the number of DPUs associated with the PCIe switch 620. In at least one embodiment, the server 602 may include, without limitation, any number of the CPUs 610, the PCIe switches 620, the GPUs 630, and/or the DPUs 640, in any combination. For example, in at least one embodiment, server 602 could include eight, sixteen, thirty-two, and/or more GPUs 630. In at least one embodiment, communication paths interconnecting various components, including but not limited to the CPU 610, the PCIe switch 620, the GPU 630, and the DPU 640, in FIG. 9 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 640 may include a network interface controller (NIC) 643, a DDR memory 644, and a non-volatile memory express (NVMe) device 646. The NIC 643 may be able to interface with a network 604, which may also interface with additional NVMe devices available to the DPU 640, such as over fabric. In an embodiment, the DPU 640 may not include the NVMe device 646. In another embodiment, the NVMe device 646 may be located on the server 602 and not on the DPU 640. In yet another embodiment, the computing environment 600 may include more than one of the NVMe device 646, such as a first NVMe device in the DPU 640 and a second first NVMe device on the server 602 an associated directly with the PCIe switch 620. In an embodiment, the DPU 640 may not include the DDR memory 644 and may include a computational storage services (CSS) in place of, or in addition to, the DDR memory 644. For example, computing environment 600 may include DPU computational storage (CS) memory 606 available to the DPU 640 as part of the CSS. The network 604 may be able to interface with the DPU CS memory 606 through the NIC 643, according to any suitable interface protocol, such as remote direct memory access (RDMA) over Ethernet, InfiniBand, Fiber Channel, etc.

The total memory of the computing environment 600 available for data storage may be expanded through the use of the DPU 640 on nodes of the system. The DPU 640 may have access to a pool 650 of memory already available to the server 602, such as double data rate (DDR) memory, on-board NVMe devices, NVMe devices over fabric, and CS. The pool 650 of memory may include at least one of the DDR memory 644, NVMe device 646, and the DPU CS memory 606. The DPU 640 may also be able to access the available memory of other DPUs as part of the pool 650, and other DPUs may be able to access the available memory of DPU 640, such as the pool 650. This available memory can be accessed and utilized for data storage, without the addition of compute resources, such as compute nodes, which would be required using other solutions. The available pool 650 accessible to the DPU 640 may be provisioned for the server 602 to expand the total memory available for data storage, such as to reduce the data storage load on the CPU 610 or the GPU 630, which can instead increase the utilization of their memory for processing. For example, during training of an AI, the model states, residual states, activation functions, and checkpoints can be stored, or offloaded, on the pool 650 accessible to the DPU 640.

### Example Data Center Environment

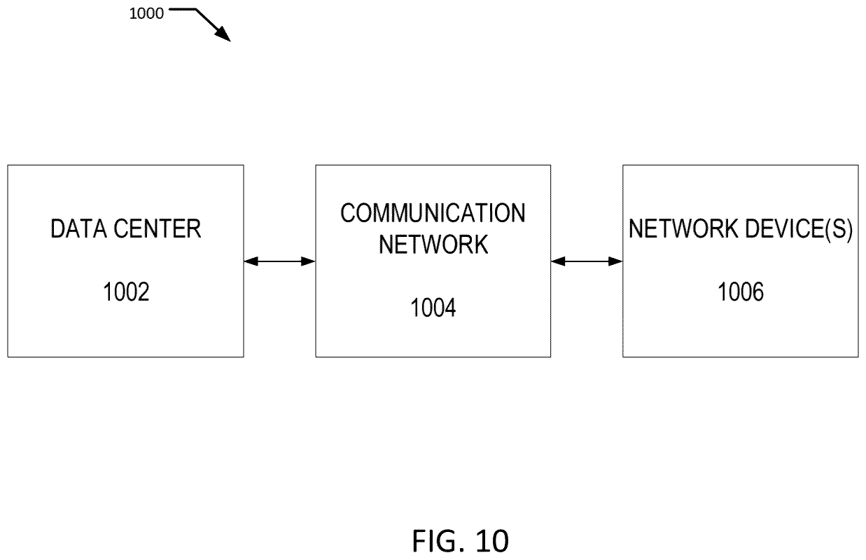

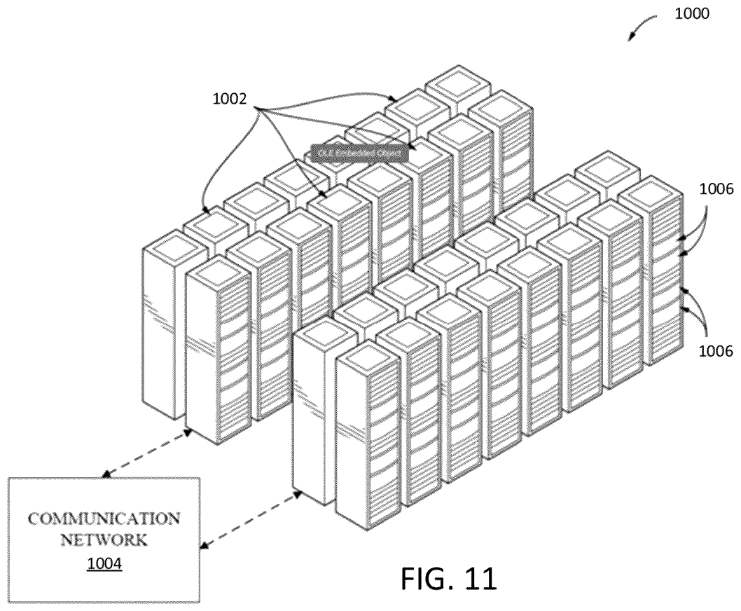

As described above, data centers, high performance compute systems 10, and/or the like are often formed of various computing components or networked devices, and communication networks formed of electrical and/or optical devices may be used to enable communication between the networked devices forming these implementations. With reference to FIGS. 10-11, for example, a network architecture 1000 may include a data center 1002, a communication network 1004, and network device(s) 1006. The network architecture 1000 may illustrate a general computing architecture within which more specific systems and/or subsystems may function. Although described hereinafter with reference to a network architecture 1000 and/or data center 1002 within which the embodiments of the present disclosure may be implemented, the present disclosure contemplates that the transceiver resiliency devices and techniques described herein may be applicable to any communication implementation without limitation.

For example, the data center 1002 may be a centralized facility designed to house computing resources and related components, for example, in a plurality of compute systems 10. The data center 1002 may comprise one or more cooling systems, such as the cooling system 20 described above and/or a liquid cooling system (an example of which is discussed below). A data center 1002 may be one or more rooms having racks, housings, and/or auxiliary equipment to house one or more servers (also referred to as compute resources) on one or more server trays (also referred to as compute trays). The data center 1002 may operate to support the infrastructure required for advanced computational tasks, for efficient, secure, and reliable operations. The data center 1002 may include the building and structural components, including power supplies, cooling systems, fire suppression systems, and physical security measures that are configured to maintain optimal operating conditions and/or protect the equipment from environmental hazards and unauthorized access. An example data center 1002 may include high-performance servers or compute nodes, often arranged in racks, such as those illustrated in FIG. 11, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The data center 1002 may include high-speed network equipment, such as network switches, routers, firewalls, and/or the like to facilitate fast and secure data transmission within the data center 1002 (e.g., between the servers or compute nodes) and between external networks. The data center 1002 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the data center 1002 may support high-performance computing tasks. Examples of various network topologies may include hierarchical networking topologies such as the fat tree topology, Slim Fly topology, Dragonfly topology, and/or the like.

The communication network 1004 may communicably couple the data center 1002 with network device(s) 1006 and other external devices for data exchange and connectivity. Examples of the communication network 1004 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. The ability of the communication network 1004 to incorporate multiple network types and configurations may allow the data center 1002 to adapt to diverse application needs, from general data communication to specialized HPC tasks. As described herein, the communication network 1004 may leverage various optical components to establish communication links (e.g., communicably couple) between components in the architecture 1000. As such, the communication network 1004 may include various optical devices, transceivers, modules, and/or the like that are configured to generate optical signals (e.g., provide optical transmitter functionality) and/or receive optical signals (e.g., provide optical receiver functionality).

The network device(s) 1006 may include a variety of computing devices capable of transmitting and receiving signals over the communication network 1004. The network device(s) 1006 may range from personal computing devices to complex server configurations. Examples include Personal Computers (PCs), laptops, tablets, smartphones, and servers. The network device(s) 1006 may facilitate user interactions with the data center 1002, allowing for data input, retrieval, and processing from remote locations. In addition to individual computing devices, the network device(s) 1006 may also include collections of servers or additional data centers. For instance, these could be other data centers similar to or the same as data center 1002. Such an interconnection may allow for the formation of a distributed computing environment for improved redundancy, load balancing, and disaster recovery capabilities. By linking multiple data centers, the network architecture 1000 may leverage geographically dispersed resources, optimizing performance and ensuring high availability.

As described herein, the data center 1002 and/or the network device(s) 1006 may include storage devices and processing circuitry for executing computing tasks, such as controlling the flow of data internally and over the communication network 1004. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (ASIC). Other non-limiting examples of processing circuitry include Integrated Circuit (IC) chips, CPUs, GPUs, microprocessors, Field Programmable Gate Arrays (FPGAs), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the data center 1002 and network device(s) 1006 may include one or more communication interfaces for facilitating wired and/or wireless communication between one another and other unillustrated elements of the network architecture 1000. These communication interfaces may include a variety of technologies, including but not limited to Ethernet ports, fiber optic connections, Wi-Fi® transceivers, Bluetooth® modules, and cellular communication modules for integration and interoperability among the various components within the network architecture 1000.

Furthermore, the present disclosure contemplates that the network architecture 1000 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the network architecture 1000 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the network architecture 1000.

In high-capacity data center networks, such as those illustrated in FIGS. 10-11, the communication network 1004 may leverage optical transceivers that transmit and receive optical signals over optical fibers or other optical communication mediums in order to establish connection between devices in the architecture 1000.

In at least one example embodiment, the data center 1002 corresponds to a collection of network devices, such as network switches (e.g., Ethernet switches, IP routers, multiservice platforms, various transmission network elements, legacy communication equipment, or in any other suitable communication system) connected with a collection of servers or compute nodes.

A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The data center 1002 may adhere to a networking topology (e.g., a hierarchal networking topology), such as a fat tree topology, a Slim Fly topology, a Dragonfly topology, and/or the like. The data center 1002 routes traffic amongst the network switches and servers therein, and at least one layer of the topology in the data center 1002 is coupled to the communication network 1004 to allow networking traffic to flow between the data center 1002 and the network device(s) 112.

The communication network 1004 may communicably couple the data center 1002 with network device(s) 1006 and other external devices for data exchange and connectivity. Examples of the communication network 1004 may include an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like.

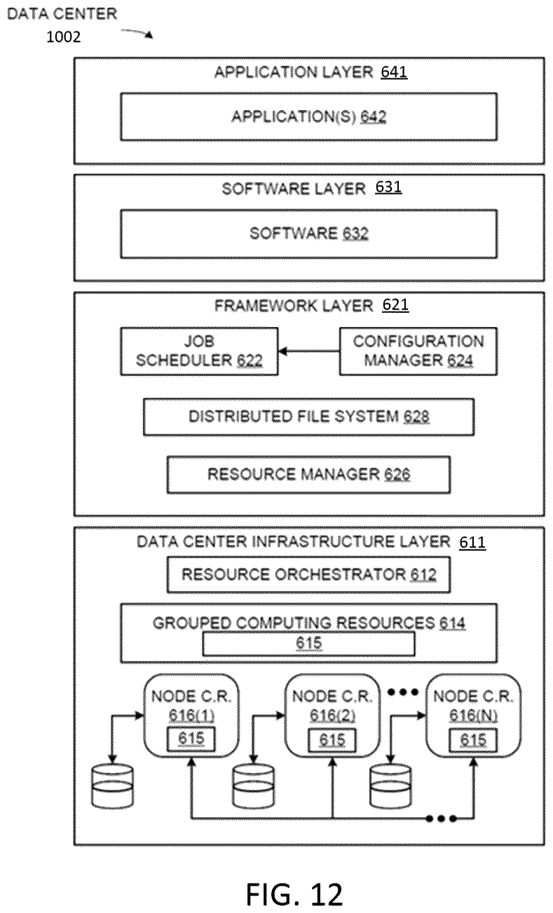

FIG. 12 illustrates an example framework of data center system, according to at least one embodiment. In at least one embodiment, data center 1002 includes a data center infrastructure layer 611, a framework layer 621, a software layer 631 and an application layer 641.

In at least one embodiment, as shown in FIG. 12, data center infrastructure layer 611 may include a resource orchestrator 612, grouped computing resources 614, and node computing resources (“node C.R.s”) 616(1)-616(N), where “N” represents a positive integer (which may be a different integer “N” than used in other figures). In at least one embodiment, node C.R.s 616(1)-616(N) may include, but are not limited to, any number of central processing units (“CPUs”) or other processors (including accelerators, field programmable gate arrays (FPGAs), graphics processors, etc.), memory storage devices 618(1)-618(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources (CRs) 614 may include separate groupings of node C.R.s housed within one or more racks, or many racks housed in data centers at various geographical locations (also not shown). In at least one embodiment, separate groupings of node C.R.s within grouped computing resources 614 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for data center 1002. In at least one embodiment, resource orchestrator 612 may include hardware, software or some combination thereof.

In at least one embodiment, as shown in FIG. 12, framework layer 621 includes a job scheduler 622, a configuration manager 624, a resource manager 626 and a distributed file system 628. In at least one embodiment, framework layer 621 may include a framework to support software 632 of software layer 631 and/or one or more application(s) 642 of application layer 641. In at least one embodiment, software 632 or application(s) 642 may respectively include web-based service software or applications, such as those provided by Amazon Web Services, Google Cloud and Microsoft Azure. In at least one embodiment, framework layer 621 may be, but is not limited to, a type of free and open-source software web application framework such as Apache Spark™ (hereinafter “Spark”) that may use distributed file system 628 for large-scale data processing (e.g., “big data”). In at least one embodiment, job scheduler 622 may include a Spark driver to facilitate scheduling of workloads supported by various layers of data center 1002. In at least one embodiment, configuration manager 624 may be capable of configuring different layers such as software layer 631 and framework layer 621 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resources 614 at data center infrastructure layer 611. In at least one embodiment, resource manager 626 may coordinate with resource orchestrator 612 to manage these mapped or allocated computing resources.

In at least one embodiment, software 632 included in software layer 631 may include software used by at least portions of node C.R.s 616(1)-616(N), grouped computing resources 614, and/or distributed file system 628 of framework layer 621. In at least one embodiment, one or more types of software may include, but are not limited to, Internet web page search software, e-mail virus scan software, database software, and streaming video content software.

In at least one embodiment, application(s) 642 included in application layer 641 may include one or more types of applications used by at least portions of node C.R.s 616(1)-616(N), grouped computing resources 614, and/or distributed file system 628 of framework layer 621. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a data center operator of data center 1002 from making possibly bad configuration decisions and possibly avoiding underused and/or poor performing portions of a data center.

In at least one embodiment, data center 1002 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 1002. In at least one embodiment, trained machine learning models corresponding to one or more neural networks may be used to infer or predict information using resources described above with respect to data center 1002 by using weight parameters calculated through one or more training techniques described herein.

A photonic neural network (PNN) system may include a number of optical interconnect structures. The optical interconnect structure may be configured to transmit/receive an optical signal (e.g., light), and direct or otherwise guide the optical signal via optical waveguides from/to one or more optical devices (e.g., modulators and photodetectors). In some scenarios, these optical waveguides may be formed in a single level. In consideration of saving a total area occupied by the corresponding photonic die, such optical waveguides may be formed (e.g., stacked) across multiple levels. When being stacked, each of the waveguides typically has a certain portion vertically overlapped with (a portion) of a neighboring waveguide. Each of the waveguides may be formed as having a transitioning portion interposed between two tapered portions to optically communicate with each other and assure the optical signal propagated therein can be saturated.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 615 are used to perform inferencing and/or training operations associated with one or more embodiments. In at least one embodiment, inference and/or training logic 615 may be used in system FIG. 6 for inferencing or predicting operations based, at least in part, on weight parameters calculated using neural network training operations, neural network functions and/or architectures, or neural network use cases described herein.

In at least one embodiment, an artificial intelligence (AI) data center infrastructure platform is provided. Examples of an AI data center infrastructure platform are Nvidia® DGX™ SuperPOD™ and DGX™ Foundry. In at least one embodiment, an AI data center infrastructure platform provides accelerated infrastructure and/or scalable performance tailored for AI such as machine learning (ML) and other high-performance computing (HPC) loads.

### Example Additional Cooling System Components

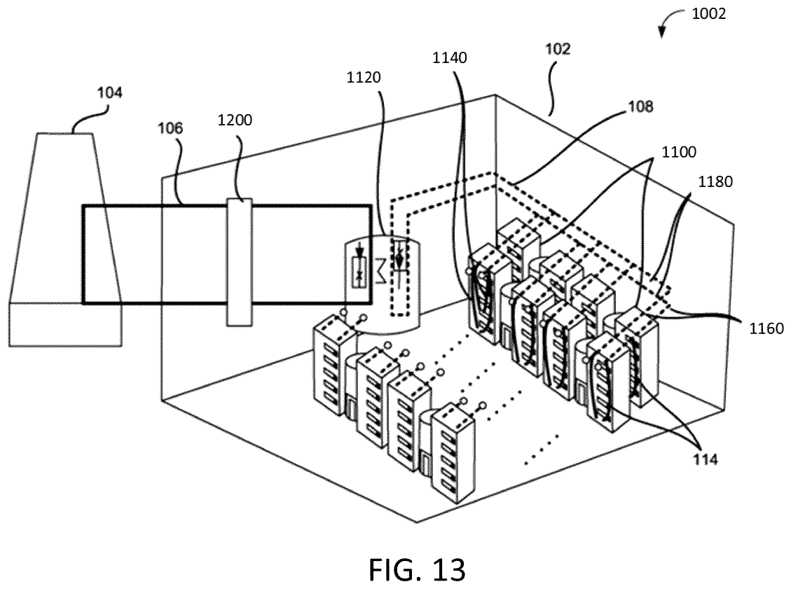

In certain embodiments, a data center may comprise liquid cooling systems and components as shown in FIG. 13 to provide additional cooling to heat sources within the data center, beyond the cooling system 20 described above. For example, for compute systems 10 and/or data centers 1002 having moderate to high cooling requirements, a liquid cooling system may be used to provide additional cooling beyond the air cooling systems described herein. In some embodiments, certain portions of a data center as discussed herein may utilize immersion cooling, while other portions of the data center may utilize air cooling systems and described herein and/or liquid cooling systems.

An example liquid cooling system may be configured to provide additional cooling for compute resources (e.g., within a compute tray 100 and/or a switch tray 200). For example, the liquid cooling system addresses heat generated by graphics processing units (GPUs), in switches, in dual inline memory module (DIMMs), or central processing units (CPUs). The liquid cooling system may be provided to address heat generated within or by processing card or tray having one or more GPUs, switches, or CPUs thereon. In at least one embodiment, each of GPUs, switches, and CPUs may generate heat separately. Collectively, the features generating heat (e.g., compute resources) within a single tray may be cooled by the air cooling system and/or liquid cooling system discussed herein. In at least one embodiment, a GPU, a CPU, or a switch may have one or more cores, and each core may generate heat.

In at least one embodiment, a data center 1002 having a liquid cooling system is supported by a cooling tower 104 located external to a data center 1002. In at least one embodiment, a cooling tower 104 dissipates heat from within a data center 1002 by acting on a primary cooling loop 106. In at least one embodiment, a cooling distribution unit (CDU) 1120 is used between a primary cooling loop 106 and a second or secondary cooling loop 108 to enable absorption of heat from a second or secondary cooling loop 108 to a primary cooling loop 106. In at least one embodiment, a secondary cooling loop 108 can access various plumbing into a compute tray and/or switch tray as required, in an aspect. In at least one embodiment, loops 106, 108 are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop 106; 108. In at least one embodiment, one or more coolant pumps may be used to maintain pressure differences within coolant loops 106, 108 to enable movement of coolant according to temperature sensors in various locations, including in a room, in one or more racks 1100, and/or in server boxes or server trays within one or more racks 1100.

In at least one embodiment, coolant in a primary cooling loop 106 and in a secondary cooling loop 108 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 1100. In at least one embodiment, a CDU 1120 is capable of sophisticated control of coolants, independently or concurrently, within provided coolant loops 106, 108. In at least one embodiment, a CDU may be adapted to control flow rate of coolant so that coolant is appropriately distributed to absorbed heat generated within associated racks 1100. In at least one embodiment, more flexible tubing 1140 is provided from a secondary cooling loop 108 to enter each server tray to provide coolant to electrical and/or computing components therein.

A heat transfer fluid utilized in a liquid cooling system generally includes water, water solutions (e.g. propylene glycol-water), brine, antifreeze, a mixture of antifreeze and water, oil, alcohol, mercury or the like or any other suitable heat conductive fluid. The heat transfer fluid may be an electrically conductive cooling liquid and may include water, deionized water, or a coolant such as R-134a, a mixture of water and additives, such as a mixture of water and ethylene glycol or a mixture of water and propylene glycol e.g. a 25% concentration of propylene glycol in deionized water. The heat transfer fluid may also be a dielectric fluid alone (e.g., not having water for purposes of this disclosure) or a water in combination with an additive including at least one dielectric fluid, such as or one or more of de-ionized water, ethylene glycol, and propylene glycol. In at least one embodiment, the heat transfer fluid may be an absorption chiller having a working fluid being a mixed solution containing lithium bromide as the absorbent material and water as the carrier material. The heat transfer fluid may also be a two-phase coolant that has a boiling point that is below the expected operating temperature of the electronic devices. Exemplary two-phase coolants include 2,3,3,3-tetrafluoropropene, 1,1,1,2-tetrafluoroethane and water.

In at least one embodiment, tubing 1180 that forms part of a secondary cooling loop 108 may be referred to as room manifolds. Separately, in at least one embodiment, further tubing 1160 may extend from row manifold tubing 1180 and may also be part of a secondary cooling loop 108 but may be referred to as row manifolds. In at least one embodiment, coolant tubing 1140 enters racks as part of a secondary cooling loop 108 but may be referred to as rack cooling manifold within one or more racks. In at least one embodiment, row manifolds 1160 extend to all racks along a row in a data center 1002. In at least one embodiment, plumbing of a secondary cooling loop 108, including coolant manifolds 1180, 1160, and 1140 may be improved by at least one embodiment herein. In at least one embodiment, a chiller 1200 may be provided in a primary cooling loop within data center 1002 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, at least a portion of heat generated within compute trays and/or switch trays of provided racks 1100 may be transferred to a coolant exiting one or more racks 1100 via flexible tubing of a row manifold 1140 of a second cooling loop 108. This transfer of heat to the coolant may be provided as additional cooling to supplement the air cooling system discussed herein. In other embodiments, some portions of a data center may utilize air cooling as discussed above, and other portions of the data center may utilize liquid cooling using a coolant as discussed here. In at least one embodiment, second coolant (in a secondary cooling loop 108) from a CDU 1120, for cooling provided racks 1100, moves towards one or more racks 1100 via provided tubing. In at least one embodiment, second coolant from a CDU 1120 passes from on one side of a room manifold having tubing 1180, to one side of a rack 1100 via a row manifold 1160, and through one side of a server tray via different tubing 1140. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 1100 comes out of different side (such as exiting side) of tubing 1140 and moves to a parallel, but also exiting side of a row manifold 1160. In at least one embodiment, from a row manifold 1160, spent second coolant moves in a parallel portion of a room manifold 1180 and is going in an opposite direction than incoming second coolant (which may also be renewed second coolant), and towards a CDU 1120.

In at least one embodiment, spent second coolant exchanges its heat with a primary coolant in a primary cooling loop 106 via a CDU 1120. In at least one embodiment, spent second coolant may be renewed (such as relatively cooled when compared to a temperature at a spent second coolant stage) and ready to be cycled back to through a second cooling loop 108 to one or more computing components. In at least one embodiment, various flow and temperature control features in a CDU 1120 enable control of heat exchanged from spent second coolant or flow of second coolant in and out of a CDU 1120. In at least one embodiment, a CDU 1120 may be also able to control a flow of primary coolant in primary cooling loop 106.

### Conclusion

In the above description, an embodiment is an example or implementation of the disclosure. The various appearances of “one embodiment,” “an embodiment,” “certain embodiments,” or “some embodiments” do not necessarily all refer to the same embodiments. Although various features of the disclosure may be described in the context of a single embodiment, the features may also be provided separately or in any suitable combination. Conversely, although the disclosure may be described herein in the context of separate embodiments for clarity, the disclosure may also be implemented in a single embodiment. Certain embodiments of the disclosure may include features from different embodiments disclosed above, and certain embodiments may incorporate elements from other embodiments disclosed above. The disclosure of elements of the disclosure in the context of a specific embodiment is not to be taken as limiting their use in the specific embodiment alone. Furthermore, it is to be understood that the disclosure can be carried out or practiced in various ways and that the disclosure can be implemented in certain embodiments other than the ones outlined in the description above.

The disclosure is not limited to those diagrams or to the corresponding descriptions. For example, flow need not move through each illustrated box or state, or in exactly the same order as illustrated and described. Meanings of technical and scientific terms used herein are to be commonly understood as by one of ordinary skill in the art to which the disclosure belongs, unless otherwise defined. While the disclosure has been described with respect to a limited number of embodiments, these should not be construed as limitations on the scope of the disclosure, but rather as exemplifications of some of the preferred embodiments. Other possible variations, modifications, and applications are also within the scope of the disclosure. Accordingly, the scope of the disclosure should not be limited by what has thus far been described, but by the appended claims and their legal equivalents.

1. A cooling system comprising:
at least one compute tray comprising one or more computing resources on a substrate and a compute tray cooling system comprising one or more internal fans and at least one heat sink attached to the substrate;
a plurality of switch trays; and
at least one fan bank comprising one or more fans at a backside of a plurality of switch trays;
wherein the compute tray cooling system and the at least one fan bank collectively provide cooling based at least in part on a workload performed by the at least one compute tray and the plurality of switch trays.

2. The cooling system of claim 1, wherein the at least one fan bank comprises a plurality of fans that collectively move air through the backside of the plurality of switch trays.

3. The cooling system of claim 2, wherein the at least one fan bank comprises a quantity of fans and wherein the plurality of switch trays is defined as a quantity of switch trays less than the quantity of fans.

4. The cooling system of claim 2, wherein the at least one fan bank comprises a plenum extending to the backside of the plurality of switch trays.

5. The cooling system of claim 4, wherein the plurality of switch trays are vented to accommodate air flow through the plenum.

6. The cooling system of claim 1, wherein the one or more fans of the at least one fan bank operate to provide cooling for the plurality of switch trays when the plurality of switch trays perform a portion of the workload.

7. The cooling system of claim 1, wherein the at least one compute tray comprises a plurality of compute resources and the heat sink comprises T-shaped heat sink fin banks extending between the plurality of compute resources on the substrate.

8. The cooling system of claim 7, wherein the compute tray further comprises a plurality of fans.

9. The cooling system of claim 8, wherein the compute resources are located between the plurality of fans and the heat sink fin banks, so that the plurality of fans blow air across the compute resources to the heat sink fin banks.

10. The cooling system of claim 8, wherein the plurality of fans of the compute tray are operable in tandem with the at least one fan bank based at least in part on whether the plurality of switch trays are operating to connect a plurality of computing resources within a plurality of compute trays.

11. A compute tray comprising:
a substrate;
a plurality of computing resources on the substrate;
a heat sink assembly on the substrate, wherein the heat sink assembly comprises fin banks arranged in a T-shape.

12. The compute tray of claim 11, further comprising a plurality of fans mounted on the substrate.

13. The compute tray of claim 12, wherein the plurality of fans are mounted in a row.

14. The compute tray of claim 13, wherein the plurality of computing resources are located between the heat sink assembly and the plurality of fans.

15. The compute tray of claim 11, further comprising a housing to enclose the substrate, the plurality of computing resources, and the heat sink assembly, wherein the substrate defines a vented rear face to allow air to pass from an interior of the housing to an exterior of the housing.

16. A method of cooling a compute system, the method comprising:
directing air across a T-shaped heat sink bank within a compute tray of a plurality of compute trays to cool compute resources within the compute tray; and
upon determining one or more switch trays are operating to connect compute resources within the plurality of compute trays, increasing air flow through the one or more switch trays using an external fan bank comprising a plurality of fans directing air through a plenum positioned at a rear of the one or more switch trays.

17. The method of claim 16, further comprising increasing a flow rate of the air directed across the T-shaped heat sink bank within the compute tray based at least in part on a temperature increasing within the compute tray.

18. The method of claim 16, wherein increasing a flow rate of the air flow through the one or more switch trays is based at least in part on a temperature increasing with the one or more switch trays.

19. The method of claim 17, wherein increasing a flow rate of air flow through the one or more switch trays comprises operating a subset of the plurality of fans of the external fan bank to direct air through the plenum positioned at the rear of the one or more switch trays.

20. The method of claim 16, wherein directing air across the T-shaped heat sink bank within a compute tray comprises operating one or more fans positioned within an interior of the compute tray.
